(19) United States
(12) Patent Application Publication
(10) Pub. No.: US 2024/0276809 A1
(43) Pub. Date: Aug. 15, 2024

(54) DISPLAY SUBSTRATE, MANUFACTURING METHOD THEREOF AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Yuanjie XU, Beijing (CN); Benlian WANG, Beijing (CN); Zhenli ZHOU, Beijing (CN); Zhiming REN, Beijing (CN); Xiaofeng YANG, Beijing (CN); Zhen WANG, Beijing (CN); Zhong LU, Beijing (CN); Lili DU, Beijing (CN); Donghua JIANG, Beijing (CN)

(21) Appl. No.: 18/564,071

(22) PCT Filed: May 27, 2021
(86) PCT No.: PCT/CN2021/096427

§ 371 Date: Nov. 25, 2023

(51) Int. Cl. H10K 59/131; H10K 59/12

(52) U.S. Cl. CPC H10K 59/131; H10K 59/1201

(57) ABSTRACT

Embodiments of the present disclosure provide a display substrate, a method for manufacturing the display substrate, and a display device. The display substrate includes: a base substrate having a wiring area; at least one wiring layer located on the base substrate, and each wiring layer includes a plurality of first wires and a plurality of second wires, which are arranged at intervals and obtained by adopting different patterning processes, in the wiring area, at least part of the first wires are arranged adjacent to the second wires, and a space between the first wire and the second wire adjacent to each other is less than 2 μm.

### TECHNICAL FIELD

The present disclosure relates to the field of display technologies, and in particular, to a display substrate, a method for manufacturing the display substrate, and a display device.

### BACKGROUND

With the rapid development of smart phones, not only a beautiful appearance of the smart phone is desired, but also more excellent visual experience is desired to be brought to a user from the smart phone. Various manufacturers start to increase the screen-to-body ratio of the smart phone, so that a full screen becomes a new competitive point of the smart phone. Along with the development of the full screen, the demand for improvement in performance and functionality is also increasing day by day. An under-screen camera can bring impact on visual and user experience to a certain extent without affecting the high screen-to-body ratio.

### SUMMARY

In an aspect, an embodiment of the present disclosure provides a display substrate, including:
a base substrate having a wiring area;
at least one wiring layer located on the base substrate, the wiring layer includes a plurality of first wires and a plurality of second wires, which are arranged at intervals and obtained by adopting different patterning processes, in the wiring area, at least part of the first wires are arranged adjacent to the second wires, and a space between the first wire and the second wire adjacent to each other is less than 2 μm.

In some implementations, in the display substrate provided in the embodiment of the present disclosure, the first wires and the second wires of the at least one wiring layer are alternately arranged at intervals.

In some implementations, in the display substrate provided in the embodiment of the present disclosure includes a display area and a frame area, the display area includes a first display area and a second display area, and a light transmittance of the first display area is greater than a light transmittance of the second display area; the first display area includes a plurality of sub-pixels arranged in an array, each sub-pixel includes a light emitting device and a pixel circuit, the pixel circuit is located in a part of the frame area adjacent to the first display area, or the second display area has a transition area adjacent to the first display area, and the pixel circuit is located in the transition area, or the pixel circuit is arranged in the second display area; the wiring area is at least partially located in the first display area, and the wiring layer is located between an anode of the light emitting device and the pixel circuit; the first wire is configured to electrically connect the light emitting device with the pixel circuit corresponding to the light emitting device, and the second wire is configured to electrically connect the light emitting device with the pixel circuit corresponding to the light emitting device.

In some implementations, in the display substrate provided in the embodiment of the present disclosure, the first wires are made of p-ITO and the second wires are made of a-ITO; a crystal grain of the p-ITO is greater than the crystal grain of the a-ITO; a crystal boundary of the p-ITO is less than a crystal boundary of the a-ITO, and a resistance of the p-ITO is less than that of the a-ITO.

In some implementations, in the display substrate provided in an embodiment of the present disclosure, the first wires are made of a-ITO and the second wires are made of at least one of doped a-Si, IZO or IGZO.

In some implementations, in the display substrate provided in the embodiment of the present disclosure, each first wire is made of a-ITO, each second wire includes a first sub-wire disposed on the base substrate and a second sub-wire disposed on a side of the first sub-wire away from the base substrate, the first sub-wire and the second sub-wire have a same pattern and are substantially overlapped, the first sub-wire is made of a-ITO, and the second sub-wire is made of at least one of doped a-Si, IZO or IGZO.

In some implementations, the display substrate provided in the embodiment of the present disclosure further includes a planarization layer disposed on a side of the wiring layer away from the base substrate, the planarization layer has first via holes at positions corresponding to the first wires and the second wires, and anodes of light emitting devices are electrically connected to the first wires and the second wires through corresponding first via holes.

In some implementations, the display substrate provided in the embodiment of the present disclosure includes a display area and a frame area, the display area includes multiple signal lines, and the frame area includes the wiring area; the first wires are configured to electrically connect with corresponding signal wires, and the second wires are configured to electrically connect with corresponding signal wires.

In some implementations, the display substrate provided in the embodiment of the present disclosure further includes a gate metal layer and a source-drain metal layer which are sequentially formed on the base substrate, the wiring layer being located in the gate metal layer and/or the source-drain metal layer.

In some implementations, in the display substrate provided in the embodiment of the present disclosure, a space between the first wire and the second wire adjacent to each other ranges from 0.15 μm to 0.35 μm, a width of the first wire is less than or equal to 2 μm, and a width of the second wire is less than or equal to 2 μm.

In some implementations, the display substrate provided in the embodiment of the present disclosure includes multiple wiring layers insulated from each other.

In some implementations, in the display substrate provided in the embodiment of the present disclosure, orthographic projections of the wiring layers on the base substrate are independently from each other.

In another aspect, an embodiment of the present disclosure further provides a method for manufacturing a display substrate, including: providing a base substrate with a wiring area; forming at least one wiring layer in the wiring area of the base substrate, and patterning the wiring area corresponding to each wiring layer by adopting different patterning processes to obtain first wirings and second wirings arranged at intervals; at least part of the first wires are arranged adjacent to the second wires, and a space between the first wire and the second wire adjacent to each other is less than 2 μm.

In some implementations, in the method provided in the embodiment of the present disclosure, the patterning the wiring area corresponding to each wiring layer by adopting different patterning processes to obtain the first wirings and the second wirings arranged at intervals includes: depositing a first conductive layer on the wiring area of the base substrate; annealing the first conductive layer; coating a first photoresist on a side of the annealed first conductive layer away from the base substrate, and exposing and developing the first photoresist to form a patterned first photoresist layer; etching the annealed first conductive layer by using a first etching material by taking the first photoresist layer as a mask, and forming the first wires arranged at intervals in the annealed first conductive layer; depositing a second conductive layer on a side of the first wires away from the base substrate, a material of the second conductive layer being the same as that of the first conductive layer not subjected to the annealing; coating a second photoresist on a side of the second conductive layer away from the base substrate, exposing and developing the second photoresist, forming a second photoresist-completely-removed region in an area of the second photoresist corresponding to the first wires, and forming a second photoresist-reserved region in an area of the second photoresist corresponding to an area between adjacent first wires to form a patterned second photoresist layer; and etching the second conductive layer by using a second etching material by taking the second photoresist layer as a mask, so as to form the second wires between every adjacent first wires.

In some implementations, in the method provided in the embodiment of the present disclosure, the patterning the wiring area corresponding to each wiring layer by adopting different patterning processes to obtain the first wirings and the second wirings arranged at intervals includes: depositing a first conductive layer on the wiring area of the base substrate; coating a first photoresist on a side of the first conductive layer away from the base substrate, and exposing and developing the first photoresist to form a patterned first photoresist layer; etching the first conductive layer by using a second etching material by taking the first photoresist layer as a mask, and forming the first wires arranged at intervals in the first conductive layer; annealing the first conductive layer formed with the first wires; depositing a second conductive layer on a side of the annealed first conductive layer away from the base substrate, a material of the second conductive layer being different from a material of the annealed first conductive layer; coating a second photoresist on a side of the second conductive layer away from the base substrate, exposing and developing the second photoresist to form a second photoresist completely-removed region in an area of the second photoresist corresponding to the first wires, and form a second photoresist-reserved region in an area of the second photoresist corresponding to an area between adjacent first wires to form a patterned second photoresist layer; and etching the second conductive layer by using a second etching material by taking the second photoresist layer as a mask, so as to form the second wires between every adjacent first wires.

In some implementations, in the method provided in the embodiment of the present disclosure, the display substrate includes a display area and a frame area, the display area includes a first display area and a second display area, and a light transmittance of the first display area is greater than that of the second display area; the first display area includes a plurality of sub-pixels arranged in an array, each sub-pixel includes a light emitting device and a pixel circuit, the pixel circuit is located in a part of the frame area adjacent to the first display area, or the second display area has a transition area adjacent to the first display area, and the pixel circuit is located in the transition area, or the pixel circuit is arranged in the second display area; the wiring area is at least partially located in the first display area, and the wiring layer is located between an anode of the light emitting device and the pixel circuit corresponding to the light emitting device; the first wire is configured to electrically connect the light emitting device with the pixel circuit corresponding to the light emitting device, and the second wire is configured to electrically connect the light emitting device with the pixel circuit corresponding to the light emitting device, the annealed first conductive layer is made of p-ITO, and the second conductive layer is made of a-ITO; the p-ITO is annealed at a high temperature, the a-ITO is annealed at a normal temperature, a crystal grain of the p-ITO is larger than that of the a-ITO, a crystal boundary of the p-ITO is smaller than that of the a-ITO, and a resistance of the p-ITO is smaller than that of the a-ITO.

In some implementations, in the method provided by the embodiment of the present disclosure, the display substrate includes a display area and a frame area, the display area including a plurality of signal lines, and the frame area including the wiring area; the first wires being configured to electrically connect corresponding signal wires, and the second wires being configured to electrically connect corresponding signal wires; the material of the second conductive layer and a material of the first conductive layer not subjected to the annealing are the same metal material.

In some implementations, in the method provided in the embodiment of the present disclosure, the patterning the wiring area corresponding to each wiring layer by adopting different patterning processes to obtain the first wirings and the second wirings arranged at intervals includes: depositing a first conductive layer in the wiring area of the base substrate; coating a first photoresist on a side of the first conductive layer away from the base substrate, and exposing and developing the first photoresist to form a patterned first photoresist layer; etching the first conductive layer by using a second etching material by taking the first photoresist layer as a mask to form the first wires arranged at intervals in the first conductive layer; depositing a second conductive layer on a side, away from the base substrate, of the first conductive layer on which the first wires are formed, a material of the second conductive layer being different from that of the first conductive layer; coating a second photoresist on a side of the second conductive layer away from the base substrate, exposing and developing the second photoresist to form a second photoresist completely-removed region in an area of the second photoresist corresponding to the first wires and form a second photoresist-reserved region in an area of the second photoresist corresponding to an area between adjacent first wires to form a patterned second photoresist layer; and etching the second conductive layer by using a first etching material by taking the second photoresist layer as a mask to form the second wires between every adjacent first wires, the second etching material being different from the first etching material.

In some implementations, in the method provided in the embodiment of the present disclosure, the patterning the wiring area corresponding to each wiring layer by adopting different patterning processes to obtain the first wirings and the second wirings arranged at intervals includes: depositing a first conductive layer in the wiring area of the base substrate; depositing a second conductive layer on a side of the first conductive layer away from the base substrate, a material of the second conductive layer being different from a material of the first conductive layer; coating a first photoresist on a side of the second conductive layer away from the substrate, and exposing and developing the first photoresist to form first photoresist completely-removed regions and first photoresist-reserved regions which are alternately arranged so as to form a patterned first photoresist layer; etching the second conductive layer by using a first etching material by taking the first photoresist layer as a mask to form a plurality of second sub-wires arranged at intervals in the second conductive layer; depositing a second photoresist on a side, away from the base substrate, of the second conductive layer formed with the second sub-wires, exposing and developing the second photoresist to form a second photoresist completely-removed region in an area of the second photoresist corresponding to the second sub-wires and form a second photoresist-reserved region in an area of the second photoresist corresponding to an area between every adjacent second sub-wires, so as to form a patterned second photoresist layer, a preset gap being existed between the second photoresist-reserved region and the second sub-wires; and etching the first conductive layer by using a second etching material by taking the second photoresist layer as a mask to form the first wires between every adjacent second sub-wires and form first sub-wires under the second sub-wires, the first sub-wire and the second sub-wire forming the second wire; the second etching material being different from the first etching material.

In some implementations, in the method provided in the embodiment of the present disclosure, the display substrate includes a display area and a frame area, the display area including a first display area and a second display area, and a light transmittance of the first display area being greater than that of the second display area; the first display area includes a plurality of sub-pixels arranged in an array, each sub-pixel includes a light emitting device and a pixel circuit, the pixel circuit is located in a part of the frame area adjacent to the first display area, or the second display area has a transition area adjacent to the first display area, and the pixel circuit is located in the transition area, or the pixel circuit is located in the second display area; the wiring area is at least partially located in the first display area, and the wiring layer is located between an anode of the light emitting device and the pixel circuit corresponding to the light emitting device; each first wire is configured to electrically connect the light emitting device with the pixel circuit corresponding to the light emitting device, and each second wire is configured to electrically connect the light emitting device with the pixel circuit corresponding to the light emitting device, a material of the first conductive layer is a-ITO, and a material of the second conductive layer includes at least one of doped a-Si, IZO or IGZO.

In some implementations, in the method provided in the embodiment of the present disclosure, the display substrate includes a display area and a frame area, the display area including a plurality of signal lines, and the frame area including the wiring area; the first wires are configured to electrically connect with corresponding signal wires, and the second wires are configured to electrically connect with corresponding signal wires, a material of the first conductive layer and a material of the second conductive layer are different metal materials.

In some implementations, the method provided in the embodiment of the present disclosure further includes: depositing a planarization layer on a side of the wiring layer away from the base substrate; patterning the planarization layer to form first via holes corresponding to the first wires and the second wires respectively; and forming a plurality of anodes on a side, away from the base substrate, of the planarization layer formed with the first via holes, the anodes being electrically connected with the first wires or the second wires through the first via holes corresponding thereto.

In some implementations, in the method provided by the embodiment of the present disclosure, the first etching material includes nitric acid.

In some implementations, in the method provided in the embodiment of the present disclosure, the second etching material includes oxalic acid.

In another aspect, an embodiment of the present disclosure further provides a display device, which includes the display substrate described above.

### BRIEF DESCRIPTION OF DRAWINGS

FIG. 1 is a schematic top view of a structure of a display substrate according to an embodiment of the present disclosure;

FIG. 2 is a schematic diagram showing a width of a wire and a space between wires in a wiring layer manufactured by a photoresist process according to the related art;

FIG. 3 is a schematic structural diagram of a display substrate according to the related art;

FIG. 4 is a schematic structural diagram of a display substrate according to an embodiment of the present disclosure;

FIG. 5 is a schematic structural diagram of another display substrate according to an embodiment of the present disclosure;

FIG. 6 is a schematic structural diagram of another display substrate according to an embodiment of the present disclosure;

FIG. 7 is a schematic top view of a structure of another display substrate according to an embodiment of the present disclosure;

FIG. 8 is a schematic structural diagram of another display substrate according to an embodiment of the present disclosure;

FIG. 9 is a schematic structural diagram of another display substrate according to an embodiment of the present disclosure;

FIG. 10 is a schematic top view of a structure of another display substrate according to an embodiment of the present disclosure;

FIG. 11 is a schematic top view of structures of a first wire and a second wire in the related art;

FIG. 12 is a schematic structural diagram of a first wire and a second wire according to an embodiment of the present disclosure;

FIG. 13 is a schematic top view of structures of the first wire and the second wire shown in FIG. 12;

FIG. 14A is a schematic structural diagram of structures of a first wire and a second wire provided in the related art;

FIG. 14B is a layout diagram of FIG. 14A;

FIG. 15A is a schematic structural diagram of a first wire and a second wire according to an embodiment of the present disclosure;

FIG. 15B is a layout diagram of FIG. 15A;

FIG. 16 is a schematic flow chart illustrating a method for manufacturing a display substrate according to an embodiment of the present disclosure;

FIGS. 17A to 17H are schematic cross-sectional views each illustrating a structure of the display substrate shown in FIG. 4 after each step is completed;

FIGS. 18A to 18G are schematic cross-sectional views each illustrating a structure of the display substrate shown in FIG. 5 after each step is completed;

FIG. 19A to 19G are schematic cross-sectional views each illustrating a structure of the display substrate shown in FIG. 6 after each step is completed.

### DETAIL DESCRIPTION OF EMBODIMENTS

To make the objects, technical solutions and advantages of the embodiments of the present disclosure more apparent, the technical solutions of the embodiments of the present disclosure will be clearly and completely described below with reference to the drawings of the embodiments of the present disclosure. It is to be understood that the described embodiments are only a few embodiments of the present disclosure, and not all embodiments. The embodiments and features of the embodiments in the present disclosure may be combined with each other without conflict. All other embodiments, which can be derived by a person skilled in the art from the described embodiments of the present disclosure without creative effort, are within the protective scope of the present disclosure.

Unless defined otherwise, technical or scientific terms used herein shall have the ordinary meaning as understood by one of ordinary skill in the art to which the present disclosure belongs. The use of “including/includes” or “comprising/comprise” and the like in the present disclosure is intended to mean that the elements or items listed before that word, and equivalents thereof, are included without exclusion of other elements or items. The terms “connected/connecting” or “coupled/coupling” and the like are not restricted to physical or mechanical connections, but may include electrical connections, whether direct or indirect. “Inner/in”, “outer/out”, “upper”, “lower”, and the like are used merely to indicate relative positional relationships, and when the absolute position of the object being described is changed, the relative positional relationships may also be changed accordingly.

It should be noted that the sizes and shapes of the various figures in the drawings are not to scale, but are merely intended to schematically illustrate the present disclosure. Like reference numerals refer to like or similar elements or elements having like or similar functions throughout.

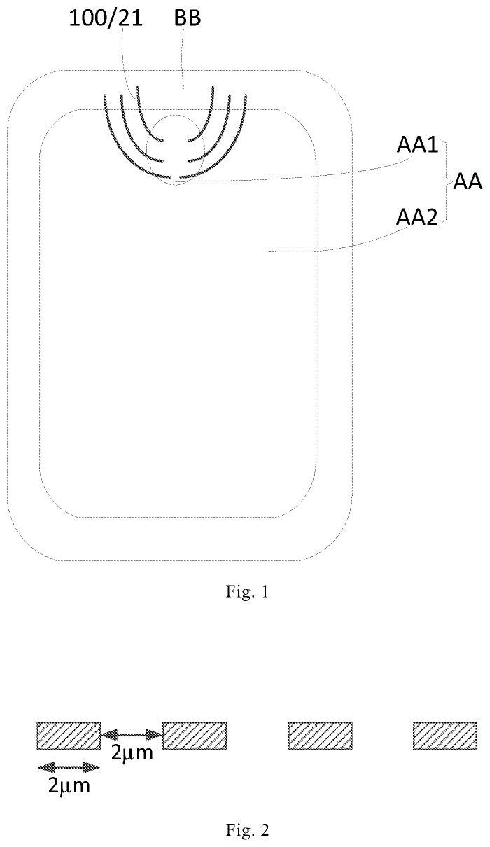

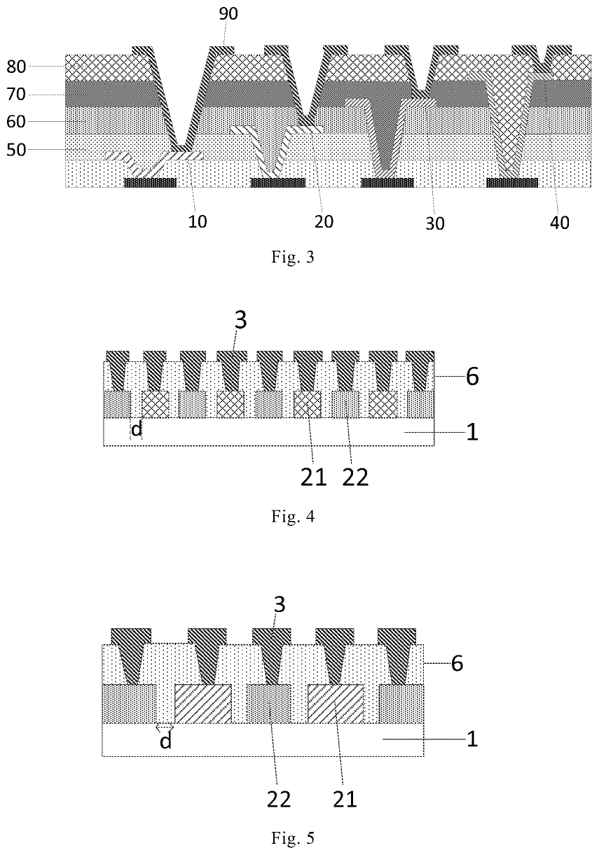

In the related art, as shown in FIG. 1, in the under-screen camera technology, a display area AA generally includes a first display area AA1 and a second display area AA2, with the second display area AA2 occupying the most portion of the display area and the first display area AA1 occupying a small portion of the display area, and the first display area AA1 is at a position where the under-screen camera is disposed. The under-screen camera refers to a front-facing camera which is disposed below the screen but does not influence the display function of the screen, and when the front-facing camera is not operating, the portion of the screen above the under-screen camera can still normally display images. Therefore, when viewing from the appearance, no hole is disposed in the screen for exposing the under-screen camera, and the full screen display effect is really achieved. However, in the current design scheme of the under-screen camera, a pixel circuit of the first display area AA1 is disposed in a frame area BB on a side of the first display area AA1 or in the second display area AA2 adjacent to the first display area AA1, taking a case where the pixel circuit of the first display area AA1 is disposed in the frame area BB on the side of the first display area AA1 as an example, the pixel circuit is connected to a light emitting device in the first display area AA1 through an ITO wire (that is, the wire is made of ITO (indium tin oxide)) 100, so as to transmit a pixel signal from the frame area to a region where the under-screen camera is disposed. As shown in FIG. 2, FIG. 2 is a schematic diagram of ITO wires in a same layer, the ITO wires are formed by performing exposure, development and etching processes on a photoresist, and because of a minimum exposure distance and a minimum exposure width of the photoresist, the ITO wires in the same layer each have a minimum wire width (Width) and have a minimum distance (space) therebetween, and currently, in a factory, the Width is generally limited to no less than about 2 μm and the space is generally limited to no less than about 2 μm, so that the number of the ITO wires in the same layer is limited. In a case where there are many light emitting devices in the first display area AA1 (especially, in the region where the under-screen camera is disposed), multiple layers of ITO wires are desired, as shown in FIG. 3, FIG. 3 illustrates an example of using four layers of ITO wires to connect pixel circuits with the light emitting devices, the four layers of ITO wires are respectively shown as 10, 20, 30, and 40, each layer of ITO wires is to be covered by an organic layer (planarization layer), that is, four planarization layers (50, 60, 70, and 80) are desired, and the four planarization layers (50, 60, 70, and 80) are to be patterned to form via holes corresponding to anodes 90 of the light emitting devices, so that the number of masks used for patterning is relatively large, which results in a long process time duration and a high cost, and an actual mass production is difficult to be achieved.

In order to solve the problem in the related art that, because the number of the ITO wires in the same layer is limited, multiple layers of ITO wires are adopted, which results in a large number of masks and a high cost, an embodiment of the present disclosure provides a display substrate, as shown in FIGS. 4 to 6, including: a base substrate 1 having a wiring area, only the wiring area being shown in FIGS. 4 to 6; at least one wiring layer 2 located on the base substrate 1, and the at least one wiring layer 2 includes a plurality of first wires 21 and a plurality of second wires 22, which are obtained by adopting different patterning processes, and are spaced apart from each other in the wiring area, and at least part of the first wires 21 are disposed adjacent to the second wires 22, and a space (distance) d between the first wire 22 and the second wire 22 adjacent to each other is less than 2 μm.

In the display substrate provided in the embodiment of the present disclosure described above, the first wires 21 and second wires 22 disposed at intervals are obtained in the same wiring layer by adopting different patterning processes, so that the first wires 21 and the second wires 22 formed by two patterning processes can be provided in the same layer (i.e., the first wires 21 and the second wires 22 are made of a same film layer), thereby the space between the wires can reduced, the space between the first wire 21 and the second line 22 adjacent to each other can be made to be less than 2 μm, allowing more wires to be provided in the same wiring layer. Therefore, for the same number of wires, the present disclosure can reduce the number of layers of the wires, thereby reducing the number of planarization layers above the wiring layers, reducing the number of masks for patterning, reducing the production cost, shortening the time consumption, and achieving a narrower bezel.

In a specific implementation, in the display substrate provided in the embodiment of the present disclosure, as shown in FIG. 4 to FIG. 6, the first wires 21 and the second wires 22 of the at least one wiring layer 2 (FIG. 4 to FIG. 6 illustrate only one wiring layer 2) may be alternately disposed at intervals. In this way, the first wires 21 arranged at intervals may be first formed on the base substrate 1 through a first patterning process, and then the second wires 22 are formed between every adjacent first wires 21 through a second patterning process, so that more wires can be arranged in the same wiring layer (i.e., first wires 21 and second wires 22 are more manufactured in the same film layer).

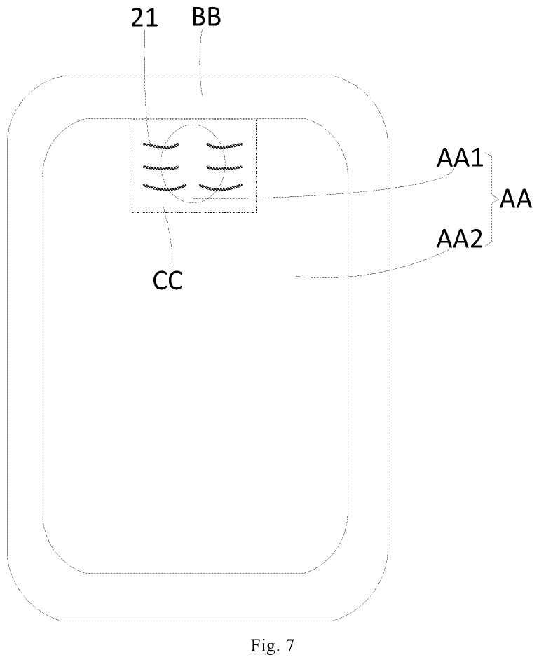

In a specific implementation, as shown in FIG. 1 and FIG. 7, the display substrate provided in the embodiment of the present disclosure includes a display area AA and a frame area BB, where the display area AA includes a first display area AA1 and a second display area AA2, and a light transmittance of the first display area AA1 is greater than a light transmittance of the second display area AA2.

The first display area AA1 includes a plurality of sub-pixels (not shown) arranged in an array, each sub-pixel includes a light emitting device and a pixel circuit (not shown), as shown in FIG. 1, the pixel circuit may be located in the frame area BB adjacent to the first display area AA1, or, as shown in FIG. 7, the second display area AA2 has a transition area CC adjacent to the first display area AA1, the pixel circuit may be located in the transition area CC, or the pixel circuit may also be arranged in the second display area AA2.

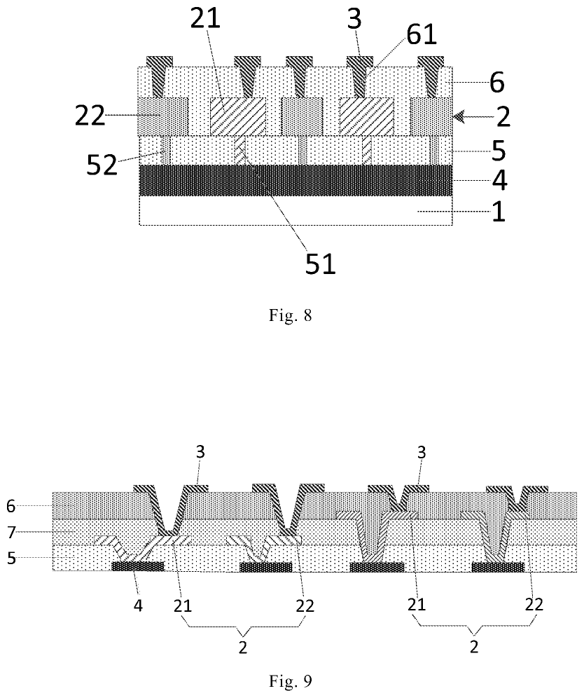

As shown in FIGS. 1 and 7, the wiring area shown in FIG. 4 is at least partially located in the first display area AA1; as shown in FIG. 8, the wiring layer 2 is located between an anode 3 of the light emitting device and a pixel circuit 4, and wiring layer 2 is electrically connected to the pixel circuit 4; the pixel circuit 4 may be, but is not limited to, of a 7T1C structure including seven transistors and one capacitor, the pixel circuit 4 includes a gate line layer, a source-drain electrode layer, and the wiring layer 2 is electrically connected with the gate line layer and/or the source-drain electrode layer of the pixel circuit 4.

As shown in FIG. 8, the first wire 21 is configured to electrically connect the anode 3 of the light emitting device to the pixel circuit 4 corresponding to the light emitting device, and the second wire 22 is configured to electrically connect the anode 3 of the light emitting device to the pixel circuit 4 corresponding to the light emitting device.

In a specific implementation, as shown in FIG. 8, the display substrate provided in the embodiment of the present disclosure further includes a first planarization layer 5 located between the pixel circuit 4 and the wiring layer 2, the first planarization layer 5 has a plurality of via holes 51 corresponding to the first wires 21, and the first planarization layer 5 has a plurality of via holes 52 corresponding to the second wires 22. the display substrate provided in the embodiment of the present disclosure further includes a second planarization layer 6 located between the wiring layer 2 and anodes 3 of light emitting devices, and the second planarization layer 6 is provided with a plurality of via holes 61 corresponding to the anodes 3.

The first wire 21 is electrically connected to the pixel circuit 4 through the via hole 51 corresponding thereto, the second wire 22 is electrically connected to the pixel circuit 4 through the via hole 52 corresponding thereto, and the anodes 3 are electrically connected to the first wires 21 and the second wires 22 through the via holes 61 corresponding thereto, respectively.

In a specific implementation, materials of indium tin oxide (ITO) may be classified into a crystalline ITO (hereinafter referred to as “p-ITO”) type and an amorphous ITO (hereinafter referred to as “a-ITO”) type, and the p-ITO and the a-ITO may be etched by using different etching materials to form corresponding wires, so that in the display substrate provided in the embodiment of the present disclosure, as shown in FIG. 4, the material of the first wires 21 may be p-ITO, and the material of the second wires 22 may be a-ITO; a crystal gain of p-ITO is larger than that of a-ITO, and a crystal boundary of the p-ITO is less than that of the a-ITO, and a resistance of the p-ITO is less than that of the a-ITO. Specifically, the a-ITO is obtained by annealing the material of ITO at a normal temperature, and the p-ITO is obtained by annealing the material of a-ITO at a high temperature, the temperature at which the annealing is performed at the high temperature may be in a range from 160° C. to 200° C., for example, may be about 160° C., 170° C., 180° C., 190° C. and 200° C.; the temperature at which the annealing is performed at the normal temperature may be in a range from 50° C. to 70° C., for example, may be about 50° C., 60° C. and 70° C. Since the p-ITO can be obtained by annealing the material of a-ITO at the high temperature (e.g., 180° C.), in the present disclosure, a layer of a-ITO may be deposited on the base substrate 1, the layer of a-ITO is etched, and then the annealing is performed on the etched layer of a-ITO at the high temperature, thereby forming the first wires 21 made of p-ITO; and then a layer of a-ITO (alpha-ITO) is deposited on the first wires 21 for manufacturing the second wires 22, etching materials adopted for etching the a-ITO and the p-ITO are different, so that the first wires 21 are not etched during etching the a-ITO above the first wires 21, and the second wires 22 made of a-ITO can be formed between the first wires 21. Therefore, in the present disclosure, the first wires 21 and the second wires 22 which are arranged at intervals can be obtained in the same wiring layer through different patterning processes, and the first wires 21 and the second wires 22 which are formed through two patterning processes can be arranged in the same layer, so that more wires can be arranged in the same wiring layer, the number of masks for patterning is reduced, the manufacturing cost is reduced, the time consumption is saved, and a narrower bezel can be realized.

In a specific implementation, in the display substrate provided in the embodiment of the present disclosure, as shown in FIG. 5, the material of the first wires 21 may be a-ITO, and the material of the second wires 22 may include at least one of doped a-Si (amorphous silicon), IZO (indium zinc oxide) or IGZO (indium gallium zinc oxide). In this way, in the embodiment of the present disclosure, a layer of a-ITO may be deposited on the base substrate 1, and the layer of a-ITO is etched to form the first wires 21 made of a-ITO; and then a film layer made of doped a-Si, IZO or IGZO is deposited on the first wires 21 for manufacturing the second wires 22, since the etching materials adopted for etching the a-ITO and the doped a-Si, IZO or IGZO are different, so that the first wires 21 made of a-ITO are not etched during etching the film layer of doped a-Si, IZO or IGZO above the first wires 21, and the second wires 22 made of doped a-Si, IZO or IGZO can be formed between the first wires 21. Therefore, in the embodiment of the present disclosure, the first wires 21 and the second wires 22 which are arranged at intervals can be obtained in the same wiring layer through different patterning processes, and the first wires 21 and the second wires 22 which are formed through two patterning processes can be arranged in the same layer, so that more wires can be arranged in the same wiring layer, the number of masks for patterning is reduced, the manufacturing cost is reduced, the time consumption is saved, and a narrower bezel can be realized.

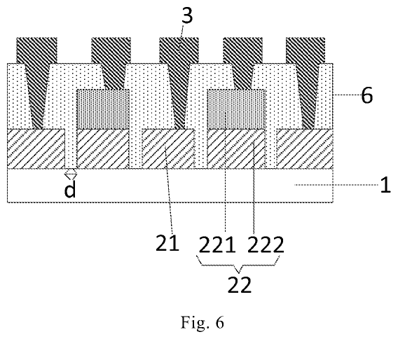

In a specific implementation, in the display substrate provided in the embodiment of the present disclosure, as shown in FIG. 6, the first wires 21 may be made of a-ITO, the second wires 22 each include a first sub-wire 221 disposed on the base substrate 1 and a second sub-wire 222 disposed on a side of the first sub-wire 221 away from the base substrate 1, patterns of each first sub-wire 221 and each second sub-wire 222 are consistent and substantially overlapped, the first sub-wires 221 may be made of a-ITO, and the second sub-wire 222 may be made of at least one of doped a-Si, IZO or IGZO. Thus, a film layer made of a-ITO may be deposited on the base substrate 1, a film layer made of doped a-Si, IZO or IGZO may be deposited on the film layer made of a-ITO (e.g., the doped a-Si is deposited), the film layer made of doped a-Si may be first etched, since the etching materials adopted for etching the a-ITO and the doped a-Si are different, the film layer made of a-ITO can not be etched during etching the film layer made of doped a-Si, so that the second sub-wires 222 made of doped a-Si can be formed on the film layer made of a-ITO, then the film layer made of a-ITO may be etched by adopting an etching material different from that for etching the film layer of doped a-Si, therefore, the first sub-wires 221 are formed under the second sub-wires 222, and the first wires 21 are formed between adjacent first sub-wires 221. Therefore, in the embodiment of the present disclosure, the first wires 21 and the second wires 22 which are arranged at intervals can be obtained in the same wiring layer through different patterning processes, and the first wires 21 and the second wires 22 which are formed through two patterning processes can be arranged in the same layer, so that more wires can be arranged in the same wiring layer, the number of masks for patterning is reduced, the manufacturing cost is reduced, the time consumption is saved, and a narrower bezel can be realized.

It should be noted that, the distance (space) d between the first wire 21 and the second wire 22 adjacent to each other and the widths of the first wire 21 and the second wire 22 in FIG. 4 to FIG. 6 are only schematic illustrations and do not represent real dimensions.

It should be noted that FIG. 8 schematically illustrates one wiring layer 2 as an example, and certainly, in a specific implementation, in a case where one wiring layer cannot meet the expectation for arranging more wires, there may be two or even more wiring layers 2, and the wiring layers 2 insulated from each other. For example, as shown in FIG. 9, FIG. 9 shows an example of two wiring layers 2, a first planarization layer 5 is disposed between the first wiring layer 2 and the pixel circuit 4 (for example, a drain of the pixel circuit), a third planarization layer 7 is disposed between the first wiring layer 2 and the second wiring layer 2, a second planarization layer 6 is disposed between the second wiring layer 2 and anodes 3 of light emitting devices, the first wire 21 and the second wire 22 in the first wiring layer 2 are electrically connected to the pixel circuits 4 corresponding thereto through via holes penetrating through the first planarization layer 5, respectively, the first wire 21 and the second wire 22 in the second wiring layer 2 are electrically connected to the pixel circuits 4 corresponding thereto through via holes penetrating through the third planarization layer 7 and the first planarization layer 5, respectively, a part of the anodes 3 are electrically connected to the first wire 21 and the second wire 22 in the first wiring layer 2 through via holes penetrating through the second planarization layer 6 and the third planarization layer 7, respectively, and another part of the anodes 3 are electrically connected to the first wire 21 and the second wire 22 in the second wiring layer 2 through via holes penetrating through the second planarization layer 6, respectively. Compared with the wiring mode shown in FIG. 3 in the related art, the wiring mode shown in FIG. 12 in the embodiment of the present disclosure can arrange more wires in the same wiring layer, that is, more wires can be arranged in the same wiring layer, so that for the same number of wires, the number of wiring layers in the present disclosure can be reduced, and then the number of planarization layers above the wiring layers can be reduced, thereby reducing the number of masks for patterning, reducing the manufacturing cost, saving the time consumption, and further realizing a narrower bezel.

It should be noted that FIG. 12 illustrates two wiring layers 2 as an example, in a case where there are more wiring layers 2, a planarization layer is disposed above each wiring layer 2, the first wiring 21 and the second wiring 22 in each subsequent layer are electrically connected to the pixel circuits corresponding thereto through via holes penetrating through the corresponding planarization layer, and the anodes 3 are electrically connected to the first wiring 21 and the second wiring 22 through via holes penetrating through the corresponding planarization layer.

In a specific implementation, in the display substrate provided in the embodiment of the present disclosure, as shown in FIG. 9, orthographic projections of the wiring layers 2 on the base substrate 1 may be arranged independently, so that the wiring layers 2 can be manufactured conveniently.

In a specific implementation, in the display substrate provided in the embodiment of the present disclosure, the wiring area shown in FIG. 4 to FIG. 6 is not only applicable to the area where the under-screen camera is located, but also applicable to a fan-out area (the fan-out area is used for connecting signal lines, such as data lines, of the display area AA to an external driving chip to implement signal transmission), as shown in FIG. 10, the display substrate includes a display area AA and a frame area BB, the display area AA includes a plurality of signal lines (for example, data lines S1, S2, S3 . . . ), and the frame area BB includes the wiring area shown in FIG. 4 to FIG. 6 (the wiring area is a fan-out area DD).

The first wires 21 are configured to electrically connect corresponding signal lines (e.g., data lines S1, S2 . . . Sn), respectively, and the second wires 22 are configured to electrically connect corresponding signal lines (e.g., data lines Sn, S (n+1) . . . ), respectively.

In a specific implementation, as shown in FIG. 10, the display substrate provided in the embodiment of the present disclosure includes a gate metal layer and a source-drain metal layer sequentially formed on the base substrate 1, and the wiring layer 2 may be located in the gate metal layer and/or the source-drain metal layer. Therefore, the first wiring layer 2 and patterns of the gate metal layer or the source-drain metal layer may be formed by one patterning process only by changing original patterning patterns during forming the gate metal layer or the source-drain metal layer, and no process for independently preparing the first wiring layer 2 is to be added, the manufacturing process flow can be simplified, the production cost is saved, and the production efficiency is improved.

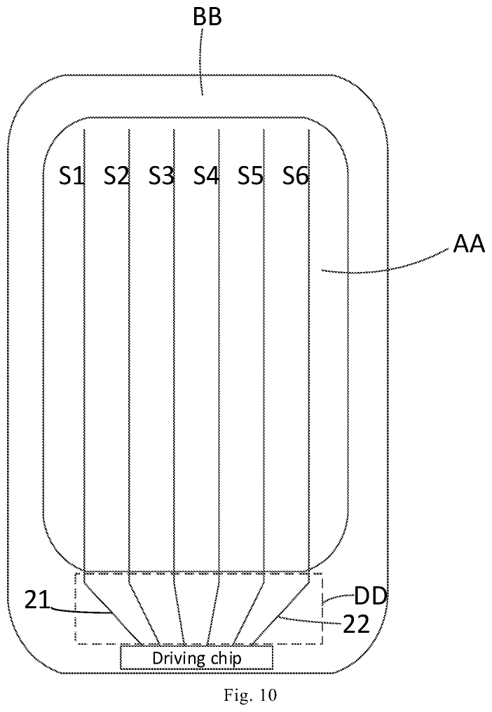

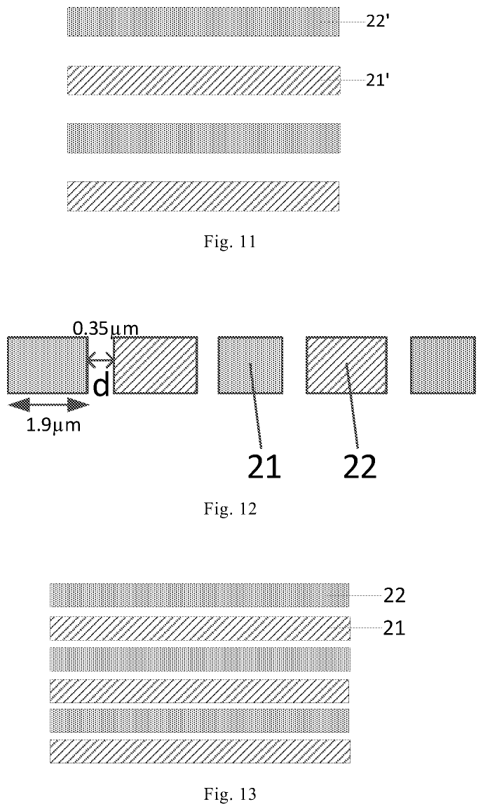

In a specific implementation, in the display substrate provided in the embodiment of the present disclosure, as shown in FIG. 4 to FIG. 6, the space d between the first wire 21 and the second wire 22, which are adjacently disposed, may be in a range from 0.15 μm to 0.35 μm, for example, may be about 0.18 μm, 0.2 μm, 0.25 μm, and 0.3 μm; the widths of the first wire 21 and the second wire 22 each may be adjusted as desired, for example, the width of the first wire 21 may be less than or equal to 2 μm, and the width of the second wire 22 may less than or equal to 2 μm. In this way, more wires can be arranged in the same wiring layer, so that the number of masks is reduced, the cost is reduced, the time consumption is saved, and a narrower bezel can be realized. Taking a width of a wiring layer being about 200 μm as an example, in the related art, a photoresist process is adopted, the width of each wire is about 2 μm and the space between wires is about 2 μm, as shown in FIG. 11, FIG. 11 is a schematic top view of a same wiring layer in the related art, and only fifty wires (21′ and 22′) can be arranged in one layer; in contrast, in the embodiment of the present disclosure, the width of each wire and the space between wires can be further reduced, as shown in FIG. 12 and FIG. 13, FIG. 12 is the cross-sectional schematic view of one wiring layer in the present disclosure, FIG. 13 is the schematic top view of FIG. 12, taking a case where the width of each of the first wires 21 and the second wires 22 is about 1.9 μm, the space d between the first wire 21 and the second wire 22 adjacent to each other is about 0.35 μm as an example, then eighty-nine wires can be arranged in the wiring layer with the width of 200 μm, thereby the number of wiring layers can be reduced, and the number of the masks for planarization layers can be reduced, and the cost is reduced.

Further, in an area available for the number of wires, each first wire 21 and/or each second wire 22 may be set to have different widths at different positions, the width of each of a part of the first wires 21 and/or the second wires 22 is less than or equal to 2 μm, and the width of each of another part of the first wires 21 and/or the second wires 22 is greater than 2 μm, so that the resistance value of the first wire 21 and/or the second wire 22 can be adjusted to adjust the load of the first wire 21 and/or the second wire 22.

Further, in a specific implementation, as shown in FIGS. 14A to 15B, FIG. 14A is a schematic cross-sectional view of two wiring layers manufactured by using a photoresist process in the related art, FIG. 14B is a schematic layout view of FIG. 14A, FIG. 15A is a schematic cross-sectional view of two wiring layers manufactured by using a photoresist process in the present disclosure, and FIG. 15B is a schematic layout view of FIG. 15A, the widths of the first wire 21 and the second wire 22, and the space between the first wire 21 and second wire 22 adjacent to each other in the embodiment of the present disclosure can be made smaller than those in the related art, therefore, if the same number of wires are manufactured in the embodiment of the present disclosure and the related art, more wires can be arranged in the same wiring layer in the embodiment of the present disclosure than in the related art, for example, only one wiring layer is desired for arranging all the wires in the present disclosure, the number of wires arranged in the same wiring layer in the related art is smaller than that in the embodiment of the present disclosure, therefore, at least two wiring layers are desired in the related art, therefore, in the present disclosure, the number of wiring layers can be reduced, the number of masks for the planarization layer is saved, and the cost is reduced.

Based on the same inventive concept, an embodiment of the present disclosure further provides a method for manufacturing the display substrate as described above, as shown in FIG. 16, the method includes: a step S1601, providing a base substrate, the base substrate being provided with a wiring area; and a step S1602, forming at least one wiring layer in the wiring area of the base substrate, and patterning in the wiring area in each wiring layer by adopting different patterning processes to obtain first wires and second wires which are arranged at intervals; at least part of the first wires are arranged adjacent to the second wires respectively, and a space between the first wire and the second wire adjacent to each other is less than 2 μm.

The method for manufacturing the display substrate shown in FIG. 4 is described in detail below, and the method may specifically include the following steps (1) to (6).

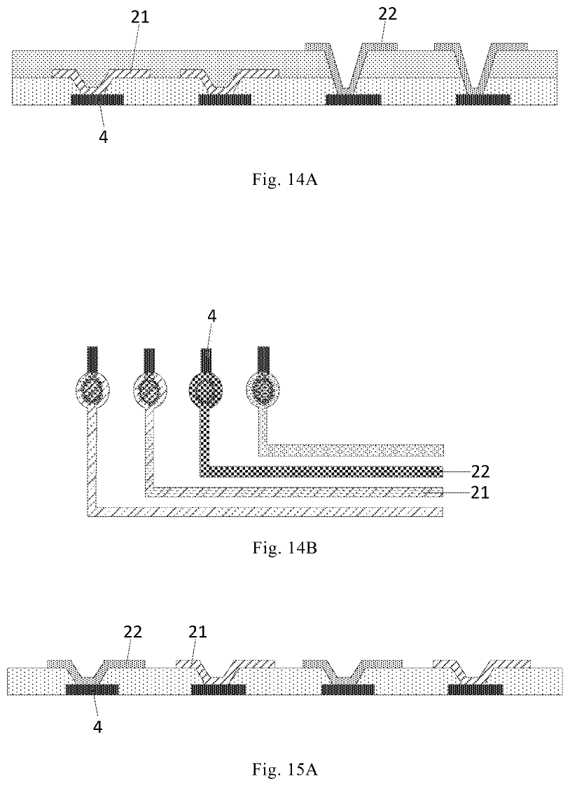

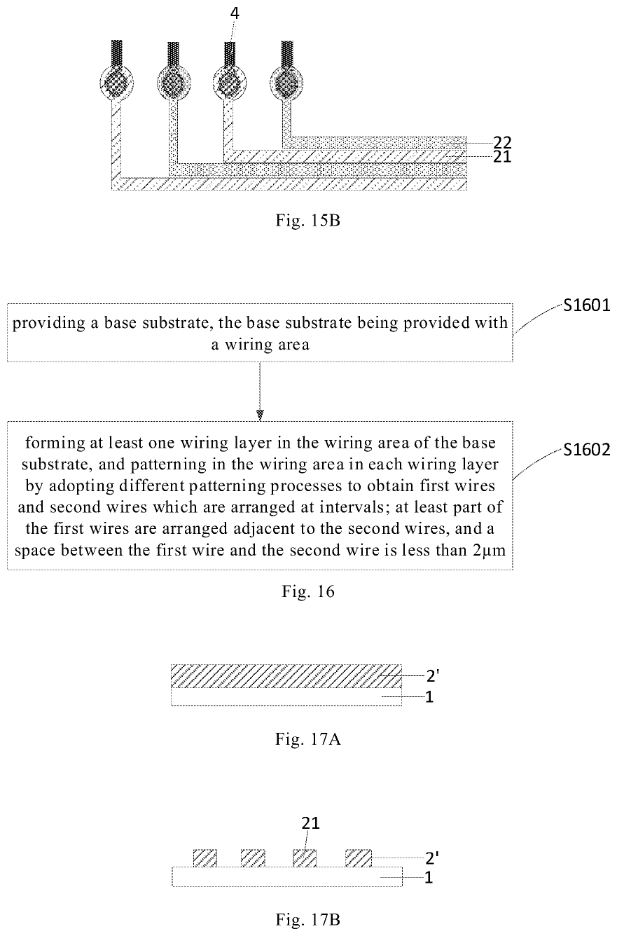

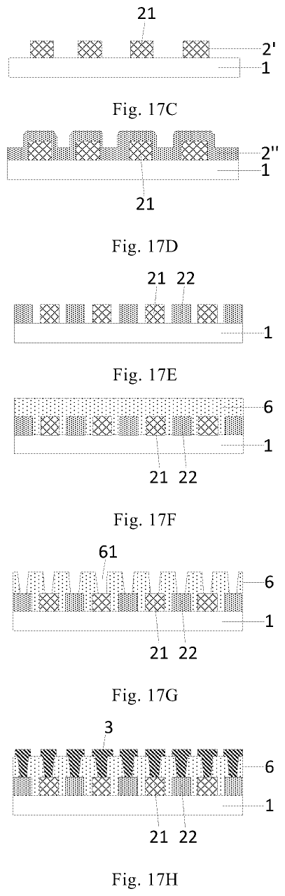

At step (1), a first conductive layer 2′ is deposited on the wiring area of the base substrate 1, as shown in FIG. 17A; in a case where the wiring area shown in FIG. 4 is located in an area where the under-screen camera is located, a material of the first conductive layer 2′ is a transparent conductive material, such as a-ITO; in a case where the wiring area shown in FIG. 4 is located in a fan-out area of the frame area, the material of the first conductive layer 2′ is a metal material, such as Ag, Al.

At step (2), as shown in FIG. 17B, a first photoresist is coated on a side of the first conductive layer 2′ away from the base substrate 1, the first photoresist is exposed and developed to form a patterned first photoresist layer, the first conductive layer 2′ (e.g., a-ITO) is etched by using a second etching material (e.g., oxalic acid) with the first photoresist layer as a mask, and a plurality of first wires 21 (before annealing) are formed at intervals in the first conductive layer 2′.

At step (3), annealing is performed on the first conductive layer 2′ formed with the plurality of first wires 21 therein, as shown in FIG. 17C, so as to obtain a plurality of annealed first wires 21 (after annealing).

At step (4), a second conductive layer 2″ is deposited on a side of the annealed first conductive layer 2′ away from the base substrate 1, a material of the second conductive layer 2″ being of a different type than the material of the annealed first conductive layer 2′, as shown in FIG. 17D. For example, the material of the annealed first conductive layer 2′ is p-ITO, and the material of the second conductive layer 2″ is a-ITO.

At step (5), a second photoresist is coated on a side of the second conductive layer 2″ away from the base substrate 1, the second photoresist is exposed and developed to form a second photoresist-completely removed region (in which the second photoresist is completely removed) in an area of the second photoresist corresponding to the first wires 21, and form a second photoresist-reserved region (in which the second photoresist is reserved) in an area corresponding to an area between adjacent first wires 21, so as to form a patterned second photoresist layer, and then the second conductive layer 2″ (made of a-ITO) is etched by using a second etching material (e.g., oxalic acid) with the second photoresist layer as a mask, so as to form second wires 22 between every adjacent first wires 21, as shown in FIG. 17E. Specifically, since the first wire 21 is made of the annealed material (e.g., p-ITO) and the second conductive layer 2″ is made of a-ITO, the annealed first wire 21 is not etched during etching the second conductive layer 2″ by using the second etching material, because the etching materials for the a-ITO and the p-ITO are different.

At step (6), as shown in FIG. 17F, a planarization layer 6 is deposited on a side of the wiring layer 2 away from the base substrate 1; the planarization layer 6 is patterned to form first via holes 61 corresponding to the first wires 21 and the second wires 22, respectively, as shown in FIG. 17G; a plurality of anodes 3 are formed on a side of the planarization layer 6 away from the base substrate 1, the anodes 3 are electrically connected to the first wires 21 or the second wires 22 through corresponding first via holes 61, as shown in FIG. 17H.

It should be noted that, in the display substrate shown in FIG. 4 manufactured by the steps (1)-(6), the first conductive layer 2′ (e.g., made of a-ITO) is etched by using a second etching material (e.g., nitric acid) and then is subjected to the annealing, certainly, the first conductive layer 2′ may be subjected to the annealing first, then the first photoresist is coated on the side of the annealed first conductive layer (e.g., made of p-ITO) away from the base substrate 1, and the first photoresist is exposed and developed to form the patterned first photoresist layer; then, the annealed first conductive layer (e.g., made of p-ITO) is etched by using the first etching material (oxalic acid) with the first photoresist layer as the mask, so that a plurality of first wires 21 (e.g., made of p-ITO) arranged at intervals are formed in the annealed first conductive layer; then a second conductive layer (a-ITO) is deposited on a side of the first wires 21 away from the base substrate, the material (a-ITO) of the second conductive layer is the same as the material (a-ITO) of the first conductive layer not subjected to the annealing; then a second photoresist is coated on a side of the second conductive layer away from the base substrate, and then the second photoresist is exposed and developed to form a second photoresist-completely-removed region in an area of the second photoresist corresponding to the first wires, and form a second photoresist-reserved region in an area of the second photoresist corresponding to an area between adjacent first wires to form a patterned second photoresist layer; and then, the second conductive layer (e.g., made of a-ITO) is etched by using a second etching material (oxalic acid) with the second photoresist layer as a mask to form second wires between every adjacent first wires.

In a specific implementation, in the method for manufacturing the display substrate provided in the embodiment of the present disclosure, as shown in FIG. 1 and FIG. 7, the display substrate may include a display area AA and a frame area BB, the display area AA includes a first display area AA1 and a second display area AA2, and a light transmittance of the first display area AA1 is greater than a light transmittance of the second display area AA2; the first display area AA1 includes a plurality of sub-pixels (not shown) arranged in an array, each of the sub-pixels includes a light emitting device and a pixel circuit (not shown), as shown in FIG. 1, the pixel circuit may be located in a portion of the frame area BB adjacent to the first display area AA1, or, as shown in FIG. 7, the second display area AA2 has a transition area CC adjacent to the first display area AA1, the pixel circuit may be located in the transition area CC, or the pixel circuit may also be located in the second display area AA2; as shown in FIGS. 1 and 7, the wiring area shown in FIG. 4 is at least partially located in the first display area AA1; as shown in FIG. 8, the wiring layer 2 is located between the anode 3 of the light emitting device and the pixel circuit 4; the first wire 21 is configured to electrically connect the anode of the light emitting device with the pixel circuit corresponding to the light emitting device, and the second wire 22 is configured to electrically connect the anode of the light emitting device with the pixel circuit corresponding to the light emitting device.

In the display substrate shown in FIG. 4 manufactured by the steps shown in FIG. 17A to FIG. 17H, the material of the annealed first conductive layer 2′ may be p-ITO, and the material of the second conductive layer 2″ may be a-ITO; the p-ITO is annealed at a high temperature, the a-ITO is annealed at a normal temperature, the crystal grain of the p-ITO is larger than that of the a-ITO, the crystal boundary of the p-ITO is smaller than that of the a-ITO, and the resistance of the p-ITO is smaller than that of the a-ITO. Specifically, p-ITO may be obtained by annealing a-ITO at a high temperature.

In a specific implementation, as shown in FIG. 10, the display substrate manufactured by the method in the embodiment of the present disclosure includes a display area AA and a frame area BB, the display area AA includes a plurality of signal lines (e.g., data lines S1, S2 . . . Sn), and the frame area BB includes a wiring area (i.e., a fan-out area DD) shown in FIG. 4.

The first wires 21 are configured to electrically connect corresponding signal lines (e.g., data lines S1, S2 . . . Sn), and the second wires 22 are configured to electrically connect corresponding signal lines (e.g., data lines Sn, S (n+1) . . . ).

In the display substrate shown in FIG. 4 manufactured by the steps shown in FIGS. 17A to 17H, the material of the second conductive layer 2″ and the material of the first conductive layer 2′ not subjected to the annealing may be the same metal material. In this way, the first wires and the second wires may be made of a metal material that can be etched by different etching materials before and after the annealing, so that the first wires and the second wires which are alternately arranged can be formed in the same wiring layer.

The method for manufacturing the display substrate shown in FIG. 5 is described in detail below, and the method may specifically include the following steps (1) to (7).

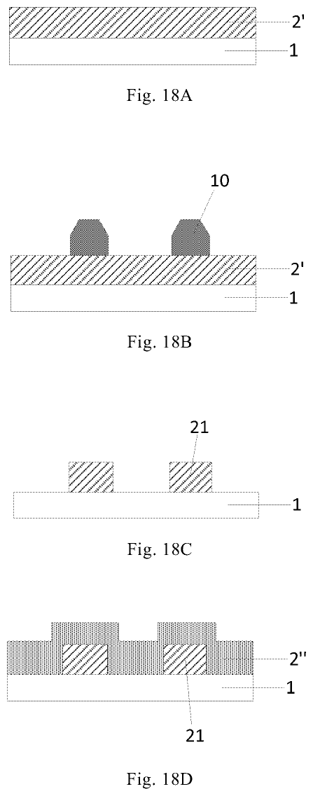

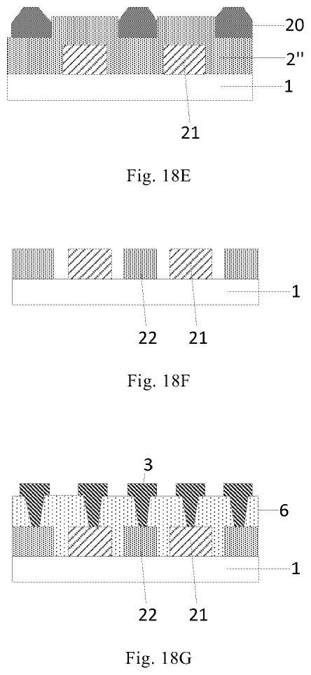

At step (1), a first conductive layer 2′ is deposited on a wiring area of the base substrate 1, as shown in FIG. 18A; in a case where the wiring area shown in FIG. 5 is located in an area where the under-screen camera is located, a material of the first conductive layer 2′ is a transparent conductive material, such as a-ITO; in a case where the wiring area shown in FIG. 5 is located in a fan-out area of the frame area, the material of the first conductive layer 2′ is a metal material, such as Ag, Al.

At step (2), a first photoresist is coated on a side of the first conductive layer 2′ away from the base substrate 1, and the first photoresist is exposed and developed to form a patterned first photoresist layer 10, as shown in FIG. 18B.

At step (3), the first conductive layer 2′ (e.g., made of a-ITO) is etched by using a second etching material (for example, oxalic acid) with the first photoresist layer 10 as a mask, so as to form a plurality of first wires 21 arranged at intervals in the first conductive layer 2′, as shown in FIG. 18C.

At step (4), a second conductive layer 2″ is deposited on a side of the first conductive layer 2′, formed with the plurality of first wires 21, away from the base substrate 1, a material of the second conductive layer 2″ is different from a material of the first conductive layer 2′, as shown in FIG. 18D. For example, the material of the first conductive layer 2′ is a-ITO and the material of the second conductive layer 2″ is doped a-Si.

At step (5), a second photoresist is coated on a side of the second conductive layer 2″ away from the base substrate 1, and the second photoresist is exposed and developed to form a second photoresist-completely-removed region in an area of the second photoresist corresponding to the first wires 21, and a second photoresist-reserved region in an area of the second photoresist corresponding to an area between adjacent first wires 21, so as to form a patterned second photoresist layer 20, as shown in FIG. 18E.

At step (6), next, the second conductive layer 2″ (e.g., made of a-ITO) is etched by using a first etching material (e.g., nitric acid) with the second photoresist layer 20 as a mask, so as to form second wires 22 between every adjacent first wires 21, the second etching material (oxalic acid) is different from the first etching material (nitric acid), as shown in FIG. 18F.

At step (7), next, a planarization layer 6 is deposited on a side of the wiring layer 2 away from the base substrate 1, the planarization layer 6 is patterned to form first via holes 61 corresponding to the first wires 21 and the second wires 22, respectively, a plurality of anodes 3 are formed on a side of the planarization layer 6, formed with the first via holes 61, away from the base substrate 1, and the anodes 3 are electrically connected to the first wires 21 or the second wires 22 through corresponding first via holes 61, as shown in FIG. 18G.

The method for manufacturing the display substrate shown in FIG. 6 is described in detail below, and the method may specifically include the following steps (1) to (7).

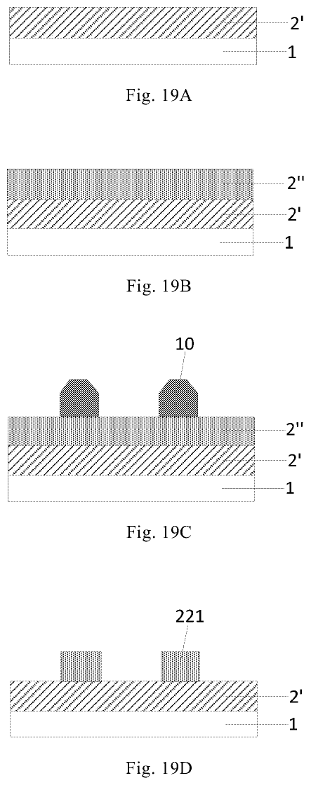

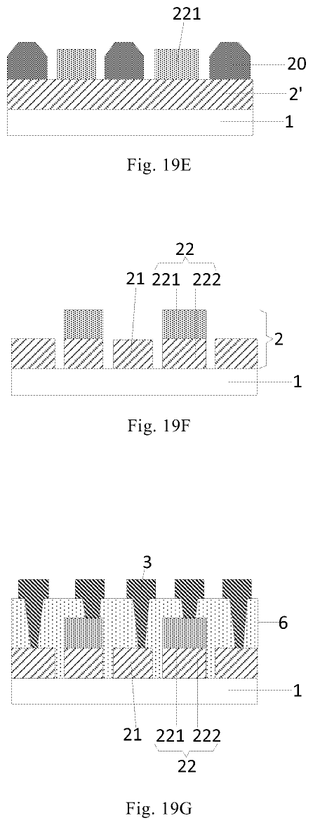

At step (1), a first conductive layer 2′ is deposited on a wiring area of the base substrate 1, as shown in FIG. 19A; in a case where the wiring area shown in FIG. 6 is located in an area where the under-screen camera is located, a material of the first conductive layer 2′ is a transparent conductive material, such as a-ITO; in a case where the wiring area shown in FIG. 6 is located in a fan-out area of the frame area, the material of the first conductive layer 2′ is a metal material, such as Ag, Al.

At step (2), a second conductive layer 2″ is deposited on a side of the first conductive layer 2′ away from the base substrate 1; a material of the second conductive layer 2″ (e.g., a-Si) and the material of the first conductive layer 2′ (a-ITO) are different, as shown in FIG. 19B.

At step (3), a first photoresist is coated on a side of the second conductive layer 2″ away from the base substrate 1, and the is exposed and developed to form first photoresist-completely-removed regions and first photoresist-reserved regions alternately arranged so as to form a patterned first photoresist layer 10, as shown in FIG. 19C.

At step (4), the second conductive layer 2″ (e.g., made of a-Si) is etched by using a first etching material (e.g. nitric acid) with the first photoresist layer 10 as a mask, so as to form a plurality of second sub-wires 222 arranged at intervals in the second conductive layer 2″, as shown in FIG. 19D.

At step (5), a second photoresist is deposited on a side of the second conductive layer 2″, formed with the second sub-wires 222, away from the base substrate 1, and the second photoresist is exposed and developed to form a second photoresist-completely-removed region in an area of the second photoresist corresponding to the second sub-wires 222 and a second photoresist-reserved region in an area of the second photoresist corresponding to an area between adjacent second sub-wires 222, a preset gap existing between the second photoresist-reserved region and the second sub-wires 222, so as to form a patterned second photoresist layer 20, as shown in FIG. 19E.

At step (6), the first conductive layer 2′ (e.g., made of a-ITO) is etched by using a second etching material (for example, oxalic acid) with the second photoresist layer 20 as a mask, the second etching material (for example, oxalic acid) is different from the first etching material (for example, nitric acid), so as to form first wires 21 between every two adjacent second sub-wires 222, and form first sub-wires 221 under the second sub-wires 222, the first sub-wire 221 and the second sub-wire 222 form a second wire 22, as shown in FIG. 19F.

At step (7), next, a planarization layer 6 is deposited on a side of the wiring layer 2 away from the base substrate 1, the planarization layer 6 is patterned to form first via holes 61 corresponding to the first wires 21 and the second wires 22, respectively, a plurality of anodes 3 are formed on a side of the planarization layer 6, formed with the first via holes 61, away from the base substrate 1, the anodes 3 being electrically connected to the first wires 21 or the second wires 22 through corresponding first via holes 61, as shown in FIG. 19G.

In a specific implementation, in the method for manufacturing the display substrate provided in the embodiment of the present disclosure, as shown in FIG. 1 and FIG. 7, the display substrate may include a display area AA and a frame area BB, the display area AA includes a first display area AA1 and a second display area AA2, and a light transmittance of the first display area AA1 is greater than a light transmittance of the second display area AA2; the first display area AA1 includes a plurality of sub-pixels (not shown) arranged in an array, each of the sub-pixels includes a light emitting device and a pixel circuit (not shown), as shown in FIG. 1, the pixel circuit may be located in a part of the frame area BB adjacent to the first display area AA1, or, as shown in FIG. 7, the second display area AA2 has a transition area CC adjacent to the first display area AA1, the pixel circuit may be located in the transition area CC, or the pixel circuit may also be arranged in the second display area AA2; as shown in FIGS. 1 and 7, the wiring area shown in FIG. 4 is at least partially located in the first display area AA1; as shown in FIG. 8, the wiring layer 2 is located between the anode 3 of the light emitting device and the pixel circuit 4 corresponding to the light emitting device; the first wire 21 is configured to electrically connect the anode of the light emitting device with the pixel circuit corresponding to the light emitting device, and the second wire 22 is configured to electrically connect the anode of the light emitting device with the pixel circuit corresponding to the light emitting device.

In the display substrate shown in FIG. 5 manufactured by the steps shown in FIGS. 18A-18G and the display substrate shown in FIG. 6 manufactured by the steps shown in FIGS. 19A-19G, the material of the first conductive layer 2′ may be a-ITO, and the material of the second conductive layer 2″ may include at least one of doped a-Si, IZO or IGZO. Specifically, the a-ITO may be etched by nitric acid, and the doped a-Si, IZO or IGZO may be etched by oxalic acid.

In a specific implementation, as shown in FIG. 10, the display substrate manufactured by the method provided in the embodiment of the present disclosure includes a display area AA and a frame area BB, the display area AA includes a plurality of signal lines (e.g., data lines S1, S2 . . . Sn), and the frame area BB includes a wiring area (i.e., a sector area DD) shown in FIG. 4.

The first wire 21 is configured to electrically connect corresponding signal lines (e.g., data lines S1, S2 . . . Sn), and the second wire 22 is configured to electrically connect corresponding signal lines (e.g., data lines Sn, S (n+1) . . . ).

In the display substrate shown in FIG. 5 manufactured by the steps shown in FIGS. 18A to 18G and the display substrate shown in FIG. 6 manufactured by the steps shown in FIGS. 19A to 19G, the material of the first conductive layer 2′ and the material of the second conductive layer 2″ may be different metal materials. In this way, the first wires and the second wires may be made of metal materials that can be etched by different etching materials, so that the first wires and the second wires which are alternately arranged can be formed in the same wiring layer.

It should be noted that the first etching material is not limited to nitric acid provided in the embodiment of the present disclosure, and the second etching material is not limited to oxalic acid provided in the embodiment of the present disclosure, as long as the first etching material and the second etching material can etch the first conductive layer and the second conductive layer, respectively.

It should be noted that wet etching may be adopted in a case where the first etching material is adopted for etching, and dry etching may be adopted in a case where the second etching material is adopted for etching; or dry etching may be adopted in a case where the first etching material is adopted for etching, and wet etching may be adopted in a case where the second etching material is adopted for etching.

It should be noted that etching the first conductive layer and the second conductive layer provided in the embodiment of the present disclosure may respectively adopt two different etching gases, and the etching processes do not affect each other; dry etching and wet etching may be respectively adopted to etch the first conductive layer and the second conductive layer, so as to achieve the purpose that two layers of wires are arranged in the same layer, but the etching of the two layers of wires are not influenced with each other.

In the present disclosure, a shape of the first display area AA1 may be a circle as shown in FIG. 1 and FIG. 7, or may be other shapes such as a rectangle, an ellipse, or a polygon, and may be designed as desired, which is not limited herein. The second display area AA2 may surround the periphery of the first display area AA1 as shown in FIGS. 1 and 7; or the second display area AA2 may surround part of the first display area AA1, for example, surround left, lower and right sides of the first display area AA1, and an upper boundary of the first display area AA1 coincides with an upper boundary of the second display area AA2.

In some implementations, in the above-mentioned display substrate provided in the embodiment of the present disclosure, as shown in FIG. 1 and FIG. 7, the first display area AA1 is configured to mount thereon with a photosensitive device, for example, a camera module. Since only the light emitting devices are present in the first display area AA1 in the present disclosure, a light transmitting area having a larger area can be provided, which is helpful for adapting to a camera module having a larger size.

Based on the same inventive concept, an embodiment of the disclosure further provides a display device, which includes the display substrate described above.

In a specific implementation, the display device further includes a photosensitive device (e.g., a camera module), and the photosensitive device is disposed in the first display area of the display substrate. Alternatively, the photosensitive device may be a camera module. The display device may be an electroluminescent display device or a photoluminescent display device. In the case that the display device is an electroluminescent display device, the electroluminescent display device may be an Organic Light-Emitting Diode (OLED) or a Quantum Dot electroluminescent display device (QLED). In the case where the display device is a photoluminescent display device, the photoluminescent display device may be a quantum dot photoluminescent display device.

The display device may be any product or component with a display function, such as a mobile phone, a tablet computer, a television, a display, a notebook computer, a digital photo frame, a navigator, an intelligent watch, a fitness wrist strap, and a personal digital assistant. It should be understood by those skilled in the art that other essential components of the display device are not described herein, and should not be construed as limitations of the present disclosure. In addition, since the principle of solving the problems of the display device is similar to that of solving the problems of the display substrate, the display device can be implemented according to the embodiment of the display substrate, and repeated descriptions are omitted.

The embodiments of the disclosure provide a display substrate and a method for manufacturing the display substrate, and a display device, the first wires and the second wires which are arranged at intervals are obtained in the same wiring layer by adopting different patterning processes, and the first wires and the second wires which are formed by two patterning processes can be arranged in the same layer, so that the space between the wires can be reduced, the space between the first wire and the second wire adjacent to each other can be made to be smaller than 2 μm, so that more wires can be arranged in the same wiring space, the number of wiring layers for the same number of wires can be reduced, the number of planarization layers above the wiring layers can be reduced, the number of masks for patterning is reduced, the manufacturing cost is reduced, the time consumption is saved, and a narrower bezel can be realized.

Although part of embodiments of the present disclosure have been described, additional variations and modifications in those embodiments may occur to those skilled in the art once they learn of the basic inventive concepts. Therefore, it is intended that the appended claims are to be interpreted as including the described embodiment and all variations and modifications that fall within the scope of the present disclosure.

It will be apparent to those skilled in the art that various variations and modifications may be made in the embodiments of the present disclosure without departing from the spirit and scope of the embodiments of the present disclosure. Thus, if such modifications and variations of the embodiments of the present disclosure are within the scope of the claims of the present disclosure and their equivalents, the present disclosure is also intended to encompass such modifications and variations.

1. A display substrate, comprising:
a base substrate having a wiring area;
at least one wiring layer located on the base substrate, the wiring layer comprises a plurality of first wires and a plurality of second wires, which are arranged at intervals and obtained by adopting different patterning processes, in the wiring area, at least part of the first wires are arranged adjacent to the second wires, and a space between the first wire and the second wire adjacent to each other is less than 2 μm.

2. The display substrate of claim 1, wherein the first wires and the second wires of the at least one wiring layer are alternately arranged at intervals.

3. The display substrate of claim 1, wherein the display substrate comprises a display area and a frame area, the display area comprising a first display area and a second display area, the first display area having a light transmittance greater than that of the second display area;
the first display area comprises a plurality of sub-pixels arranged in an array, each sub-pixel comprises a light emitting device and a pixel circuit, the pixel circuit is located in a part of the frame area adjacent to the first display area, or the second display area has a transition area adjacent to the first display area, and the pixel circuit is located in the transition area, or the pixel circuit is arranged in the second display area;
the wiring area is at least partially located in the first display area, and the wiring layer is located between an anode of the light emitting device and the pixel circuit;
the first wire is configured to electrically connect the light emitting device with the pixel circuit corresponding to the light emitting device, and the second wire is configured to electrically connect the light emitting device with the pixel circuit corresponding to the light emitting device.

4. The display substrate of claim 3, wherein the first wires are made of p-ITO and the second wires are made of a-ITO; a crystal grain of the p-ITO is greater than a crystal grain of the a-ITO; a crystal boundary of the p-ITO is less than a crystal boundary of the a-ITO, and a resistance of the p-ITO is less than that of the a-ITO.

5. The display substrate of claim 3, wherein the first wires are made of a-ITO and the second wires are made of at least one of doped a-Si, IZO or IGZO.

6. The display substrate of claim 3, wherein each first wire is made of a-ITO, each second wire comprises a first sub-wire disposed on the base substrate and a second sub-wire disposed on a side of the first sub-wire away from the base substrate, the first sub-wire and the second sub-wire have a same pattern and are substantially overlapped, the first sub-wire is made of a-ITO, and the second sub-wire is made of at least one of doped a-Si, IZO or IGZO.

7. The display substrate of claim 1, further comprising a planarization layer disposed on a side of the wiring layer away from the base substrate, wherein the planarization layer has first via holes at positions corresponding to the first wires and the second wires, and anodes of light emitting devices are electrically connected to the first wires and the second wires through the first via holes corresponding thereto.

8. The display substrate of claim 1, wherein the display substrate comprises a display area and a frame area, the display area comprising a plurality of signal lines, and the frame area comprising the wiring area;
the first wires are configured to electrically connect with corresponding signal wires, and the second wires are configured to electrically connect with corresponding signal wires, and wherein
a display substrate further comprises a gate metal layer and a source-drain metal layer which are sequentially formed on the base substrate, the wiring layer being located in the gate metal layer and/or the source-drain metal layer.

9. (canceled)

10. The display substrate of claim 1, wherein a space between the first wire and the second wire adjacent to each other ranges from 0.15 μm to 0.35 μm, a width of the first wire is less than or equal to 2 μm, and a width of the second wire is less than or equal to 2 μm.

11. The display substrate of claim 1, wherein the display substrate comprises multiple wiring layers insulated from each other, and orthographic projections of the wiring layers on the base substrate are independently from each other.

12. (canceled)

13. A method for manufacturing a display substrate, comprising:
providing a base substrate with a wiring area;
forming at least one wiring layer in the wiring area of the base substrate, and patterning the wiring area corresponding to each wiring layer by adopting different patterning processes to obtain first wirings and second wirings arranged at intervals; at least part of the first wires are arranged adjacent to the second wires, and a space between the first wire and the second wire adjacent to each other is less than 2 μm.

14. The method of claim 13, wherein the patterning the wiring area corresponding to each wiring layer by adopting different patterning processes to obtain the first wirings and the second wirings arranged at intervals comprises:
depositing a first conductive layer on the wiring area of the base substrate;
annealing the first conductive layer;
coating a first photoresist on a side of the annealed first conductive layer away from the base substrate, and exposing and developing the first photoresist to form a patterned first photoresist layer;
etching the annealed first conductive layer by using a first etching material by taking the first photoresist layer as a mask, and forming the first wires arranged at intervals in the annealed first conductive layer;
depositing a second conductive layer on a side of the first wires away from the base substrate, a material of the second conductive layer being the same as that of the first conductive layer not subjected to the annealing;
coating a second photoresist on a side of the second conductive layer away from the base substrate, exposing and developing the second photoresist, forming a second photoresist-completely-removed region in an area of the second photoresist corresponding to the first wires, and forming a second photoresist-reserved region in an area of the second photoresist corresponding to an area between adjacent first wires to form a patterned second photoresist layer; and
etching the second conductive layer by using a second etching material by taking the second photoresist layer as a mask, so as to form the second wires between every adjacent first wires,
or,
the patterning the wiring area corresponding to each wiring layer by adopting different patterning processes to obtain the first wirings and the second wirings arranged at intervals comprises:
depositing a first conductive layer on the wiring area of the base substrate;
coating a first photoresist on a side of the first conductive layer away from the base substrate, and exposing and developing the first photoresist to form a patterned first photoresist layer;
etching the first conductive layer by using a second etching material by taking the first photoresist layer as a mask, and forming the first wires arranged at intervals in the first conductive layer;
annealing the first conductive layer formed with the first wires;
depositing a second conductive layer on a side of the annealed first conductive layer away from the base substrate, a material of the second conductive layer being different from a material of the annealed first conductive layer;
coating a second photoresist on a side of the second conductive layer away from the base substrate, exposing and developing the second photoresist to form a second photoresist completely-removed region in an area of the second photoresist corresponding to the first wires, and form a second photoresists-reserved region in an area of the second photoresist corresponding to an area between adjacent first wires to form a patterned second photoresist layer; and
etching the second conductive layer by using a second etching material by taking the second photoresist layer as a mask, so as to form the second wires between every adjacent first wires.

15. (canceled)

16. The method of claim 14, wherein the display substrate comprises a display area and a frame area, the display area comprises a first display area and a second display area, and a light transmittance of the first display area is greater than that of the second display area; the first display area comprises a plurality of sub-pixels arranged in an array, each sub-pixel comprises a light emitting device and a pixel circuit, the pixel circuit is located in a part of the frame area adjacent to the first display area, or the second display area has a transition area adjacent to the first display area, and the pixel circuit is located in the transition area, or the pixel circuit is arranged in the second display area; the wiring area is at least partially located in the first display area, and the wiring layer is located between an anode of the light emitting device and the pixel circuit corresponding to the light emitting device; the first wire is configured to electrically connect the light emitting device with the pixel circuit corresponding to the light emitting device, and the second wire is configured to electrically connect the light emitting device with the pixel circuit corresponding to the light emitting device,
the annealed first conductive layer is made of p-ITO, and the second conductive layer is made of a-ITO; the p-ITO is annealed at a high temperature, the a-ITO is annealed at a normal temperature, a crystal grain of the p-ITO is larger than that of the a-ITO, a crystal boundary of the p-ITO is smaller than that of the a-ITO, and a resistance of the p-ITO is smaller than that of the a-ITO.

17. The method of claim 14, wherein the display substrate comprises a display area and a frame area, the display area comprising a plurality of signal lines, and the frame area comprising the wiring area; the first wires being configured to electrically connect corresponding signal wires, and the second wires being configured to electrically connect corresponding signal wires;
the material of the second conductive layer and a material of the first conductive layer not subjected to the annealing are the same metal material.

18. The method of claim 13, wherein the patterning the wiring area corresponding to each wiring layer by adopting different patterning processes to obtain the first wirings and the second wirings arranged at intervals comprises:
depositing a first conductive layer in the wiring area of the base substrate;
coating a first photoresist on a side of the first conductive layer away from the base substrate, and exposing and developing the first photoresist to form a patterned first photoresist layer;
etching the first conductive layer by using a second etching material by taking the first photoresist layer as a mask to form the first wires arranged at intervals in the first conductive layer;
depositing a second conductive layer on a side, away from the base substrate, of the first conductive layer formed thereon with the first wires, a material of the second conductive layer being different from that of the first conductive layer;
coating a second photoresist on a side of the second conductive layer away from the base substrate, exposing and developing the second photoresist to form a second photoresist completely-removed region in an area of the second photoresist corresponding to the first wires and form a second photoresist-reserved region in an area of the second photoresist corresponding to an area between adjacent first wires to form a patterned second photoresist layer; and
etching the second conductive layer by using a first etching material by taking the second photoresist layer as a mask to form the second wires between every adjacent first wires, the second etching material being different from the first etching material,
or,
the patterning the wiring area corresponding to each wiring layer by adopting different patterning processes to obtain the first wirings and the second wirings arranged at intervals comprises:
depositing a first conductive layer in the wiring area of the base substrate;
depositing a second conductive layer on a side of the first conductive layer away from the base substrate, a material of the second conductive layer being different from a material of the first conductive layer;
coating a first photoresist on a side of a second conductive layer away from the substrate, and exposing and developing the first photoresist to form first photoresist completely-removed regions and a first photoresist-reserved regions which are alternately arranged so as to form a patterned first photoresist layer;
etching the second conductive layer by using a first etching material by taking the first photoresist layer as a mask to form a plurality of second sub-wires arranged at intervals in the second conductive layer;
depositing a second on a side, away from the base substrate, of the second conductive layer formed thereon with the second sub-wires, exposing and developing the second photoresist to form a second photoresist completely-removed region in an area of the second photoresist corresponding to the second sub-wires and form a second photoresist-reserved region in an area of the second photoresist corresponding to an area between every adjacent second sub-wires, so as to form a patterned second photoresist layer, a preset gap being existed between the second photoresist-reserved region and the second sub-wires; and
etching the first conductive layer by using a second etching material by taking the second photoresist layer as a mask to form the first wires between every adjacent second sub-wires and form first sub-wires under the second sub-wires, the first sub-wire and the second sub-wire forming the second wire, the second etching material being different from the first etching material.

19. (canceled)

20. The method of claim 18, wherein the display substrate comprises a display area and a frame area, the display area comprising a first display area and a second display area, and a light transmittance of the first display area being greater than that of the second display area; the first display area comprises a plurality of sub-pixels arranged in an array, each sub-pixel comprises a light emitting device and a pixel circuit, the pixel circuit is located in a part of the frame area adjacent to the first display area, or the second display area has a transition area adjacent to the first display area, and the pixel circuit is located in the transition area, or the pixel circuit is located in the second display area; the wiring area is at least partially located in the first display area, and the wiring layer is located between an anode of the light emitting device and the pixel circuit corresponding to the light emitting device; each first wire is configured to electrically connect the light emitting device with the pixel circuit corresponding to the light emitting device, and each second wire is configured to electrically connect the light emitting device with the pixel circuit corresponding to the light emitting device,
a material of the first conductive layer is a-ITO, and a material of the second conductive layer comprises at least one of doped a-Si, IZO or IGZO.

21. The method of claim 18, wherein the display substrate comprises a display area and a frame area, the display area comprising a plurality of signal lines, and the frame area comprising the wiring area; the first wires are configured to electrically connect with corresponding signal wires, and the second wires are configured to electrically connect with corresponding signal wires,
a material of the first conductive layer and a material of the second conductive layer are different metal materials.

22. The method of claim 20, further comprising:
depositing a planarization layer on a side of the wiring layer away from the base substrate;
patterning the planarization layer to form first via holes corresponding to the first wires and the second wires respectively; and
forming a plurality of anodes on a side, away from the base substrate, of the planarization layer formed with the first via holes, the anodes being electrically connected with the first wires or the second wires through the first via holes corresponding thereto.

23. The method of claim 14, wherein the first etching material comprises nitric acid, and the second etching material comprises oxalic acid.

24. (canceled)

25. A display device, comprising the display substrate of claim 1.
